(19) United States
(12) Patent Application Publication
(10) Pub. No.: US 2024/0397610 A1
(43) Pub. Date: Nov. 28, 2024

(54) OFFSET VOIDING SCHEME FOR VERTICAL INTERCONNECTS

(71) Applicant: Intel Corporation, Santa Clara, CA (US)

(72) Inventors: Aik Hong Tan, Sungai Petani (MY); Jackson Chung Peng Kong, Georgetown (MY); Li Wern Chew, Georgetown (MY)

(73) Assignee: Intel Corporation, Santa Clara, CA (US)

(21) Appl. No.: 18/201,656

(22) Filed: May 24, 2023

(51) Int. Cl. H05K 1/02; H01L 21/48; H01L 23/498; H01L 23/66; H05K 3/40

(52) U.S. Cl. CPC H05K 1/0222; H01L 21/4857; H01L 21/486; H01L 23/49822; H01L 23/49838; H01L 23/66; H05K 3/4038; H01L 2223/6688; H05K 2201/09481

(57) ABSTRACT

An integrated circuit (IC) package includes a via extending through a stack of antipads in a stack of layers, and the stack of antipads has an antipad with a shorter diameter between antipads with longer diameters. The via may have first and second connections and first and second pads at or over and under the antipads. The longer diameters (over and under the shorter diameter) may be equal. Intervening antipads of intermediate size may be between the smallest antipads and the largest antipads. An antipad void profile may be tapered and concave, with flatter slopes nearer the upper and lower ends of the via and steeper slopes near a via midpoint. A second via may be adjacent the first via. One or more other vias may have an aligned (rather than a tapered) profile.

### BACKGROUND

Vias and associated voids or gaps in conductor layers in substrates may have mechanical, electrical, or other issues, which may degrade system performance, waste package or board space, or otherwise constrain device or system layouts.

New structures and techniques are needed to improve system performance or reduce system or device sizes.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A and 1B illustrate isometric views of vias in an integrated circuit (IC) package and adjacent an IC die, in accordance with some embodiments;

FIGS. 2A and 2B illustrate cross-sectional profile views of an IC package with antipad voids in multiple layers and a via through the antipads, in accordance with some embodiments;

FIG. 3 illustrates an isometric view of an IC package having traces with connections to, and antipads around, a via in a tapered antipad profile, in accordance with some embodiments;

FIGS. 4A, 4B, and 4C illustrate isometric and schematic views of vias, antipads, and adjacent structures, in accordance with some embodiments;

FIGS. 5A and 5B illustrate a cross-sectional profile and plan views of an IC package with antipads in multiple layers and vias through antipads, in accordance with some embodiments;

FIG. 6 is a plurality of plots of modeled data comparing various circuit parameters for vias in a differential-pair configuration, in accordance with some embodiments;

FIGS. 7A, 7B, and 7C illustrate plots for comparison of electrical performances of various modeled vias, in accordance with some embodiments;

FIG. 8 is a flow chart of methods for forming a via with a tapered antipad void profile, in accordance with some embodiments;

FIG. 9 illustrates a diagram of an example data server machine employing an IC device having a via with a tapered antipad profile, in accordance with some embodiments; and

FIG. 10 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Structures and techniques are disclosed that improve the performance of integrated circuit (IC) devices with vias in packages having IC dies. An improved via antipad profile provides electrical and mechanical benefits in these IC packages. A via with a tapered antipad void profile may approximate the electrical performance of a wide, stacked void profile while having improved mechanical performance. This enhanced mechanical performance may allow for increased routing flexibility and enable high interconnect densities, for example, under an IC die in an IC package substrate. Tighter routing and interconnect layouts may allow for smaller IC package sizes.

Conductive vias in IC packages may be used to connect structures in different levels of the IC package. For example, vias may make electrical connections (e.g., to conductive traces) at one or more levels of the package. Vias may also have pads (e.g., conductive discs centered on the via) at one or more levels of the package, for example, at any level(s) where the conductive via connects to a conductive trace. The conductive pads may provide advantages (for example, electrical, mechanical, manufacturing, or reliability advantages). A via may also have antipads around the via at one or more levels along the via.

Antipads are regions around a via where certain conductive structures are not present. For example, an antipad may be an opening or void in a conductive plane, such as a circular hole in a plane or thin layer of copper. During design of the IC package (e.g., when laying out a package substrate coupled to an IC die and including a conductive via), antipads may be “keepout” areas around a via where conductors are generally forbidden from being placed. A keepout area may be defined by a radius around, or diameter centered on, the via. These keepouts may be defined by other means or dimensions. While the conductive via (and structures, such as traces, electrically connected to the via) may be within the antipad, other conductors are excluded. Such excluded conductors may be adjacent conductive traces that are routed nearby, but that should maintain the antipad's minimum required distance from the via. As discussed, in otherwise continuous layers of copper (or other conductors), an antipad may present as a hole in the conductive layer. These holes or voids without excluded conductors may instead be filled with an insulator material, such as a dielectric material separating conductive layers in a package substrate.

In contrast to a tapered void profile, stacked (or vertically aligned) antipad voids in IC packages may have mechanical issues, e.g., susceptibility to shear forces. For this reason, manufacturing design rules may forbid voids with aligned edges in vertically adjacent conductor layers in certain regions, for example, under IC dies. These design rules may address problem regions when a package is subjected to vertical forces, e.g., clamping or other retention forces in a socketed system, such as during product validation testing. But these design rules may also interfere with package routing. For example, multilevel vias may be problematic as both vital for input/output (I/O) interconnects under IC dies and especially vulnerable to shear forces. High-speed interconnects may be sensitive to impedance mismatches and particularly problematic as increased void sizes (e.g., with larger diameters or radii) may improve impedance matching and signaling performance, but also increase susceptibility to vertical forces. The package routing or other layout issues caused by these mechanical vulnerabilities and/or associated design rules may result in wasted area during layout. Traces may need to be routed out from under an IC die to a via and back under the IC die. I/O interconnects may need to be laid out less densely to allow for a single, tall via to be replaced by more and shorter vias spread out laterally. An improved via antipad profile would enable smaller IC packages while permitting robust reliability (and validation, etc.) results while not degrading device electrical performance.

The disclosed antipad profile allows for wider antipad voids at the top and bottom of a via (e.g., around conductive pads there) while having one or more narrower antipad voids between the top and bottom. An improved antipad profile provides sufficient mechanical strength (such as resilience against shear, vertical forces), as well as the electrical benefits of increased void sizes. A tapered or concave profile reduces capacitance between conductors adjacent the via and conductive pads at via ends with more spacious antipads, while allowing for smaller antipads and gaps between conductors vertically further from the conductive pads (e.g., between the via and a ground plane near a midpoint of the via). A concave profile may have one or more narrowest antipad void(s) at a waist (or midpoint) of the via, antipad voids with increasing diameters moving away from the waist, and widest antipad voids at the top and bottom. Other profiles may have antipads with borders otherwise vertically misaligned.

A tapered profile reduces constraints on vertical routing, allowing routing between nearby or even the uppermost and lowermost levels in a package substrate, and even directly under an IC die. A tapered profile enables a smaller package form factor by this improved vertical routing, as well as by eliminating otherwise necessary lateral routing back and forth from under and to the sides of an IC die. A tapered profile also enables a smaller package by allowing for dense layouts of I/O interconnects under IC dies. A smaller package provides packaging and layout flexibility and reduces costs. A tapered profile also improves signaling performance, e.g., insertion loss (IL), reflection loss (RL), and impedance (Z) continuity for a single via or pair of vias, as will be discussed elsewhere herein, and by allowing for increased spacing between traces (e.g., in a same-sized package) by reducing the need for extra routing.

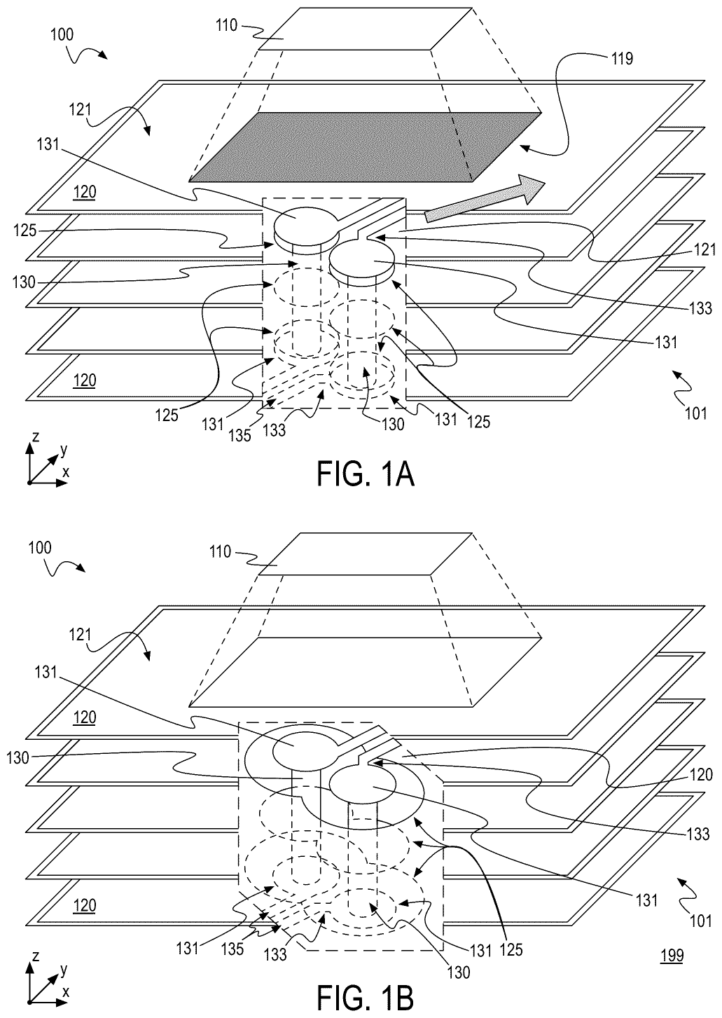

FIGS. 1A and 1B illustrate isometric views of vias 130 in an IC package 100 and adjacent an IC die 110, in accordance with some embodiments. Vias 130 are shown in an inset view, slightly magnified relative to other portions of package 100. Vias 130 extend through a stack of layers 120 and through a stack of antipad voids 125 in conductors 121 and layers 120. The extent of antipad voids 125 in conductors 121 are apparent from the edges of conductors 121 around vias 130. Conductors 121 and layers 120 are in or on a package substrate 101. FIG. 1A shows vertically aligned antipad voids 125 around via 130, with all antipad voids 125 having a same diameter centered on via 130, which may be characterized as a stacked or vertically aligned void or antipad profile. Increasing the antipad diameter may improve electrical performance of via 130, but degrade mechanical performance (e.g., shear strength). Since such a large, vertically aligned, multilevel void around via 130 may cause structural weaknesses, design rules may forbid locating vias 130 under the IC die 110 and the keep-out area 119 associated with the die shadow. Vias 130 with vertically aligned antipad voids 125 may be limited to locations to the sides of, or lateral to, keep-out area 119 (e.g., in one or more of any of the x and y directions). Such a limitation may constrain routing in and through package 100, limit I/O interconnect density under IC die 110, and increase the necessary size of IC package 100.

FIG. 1B illustrates IC package 100 with via 130 through multiple layers 120 and multiple antipad voids 125 having offset or staggered edges in conductors 121. Antipad voids 125 in this improved profile may have various diameters or widths. In the example of FIG. 1B, each via 130 has a stack of antipad voids 125 that are coaxial, but a middle antipad void 125 in each stack is smaller (e.g., has a smaller radius and diameter and covers a smaller area) than each antipad void 125 over and under the middle antipad void 125. A radius of antipad void 125 may refer to the lateral distance from an axis of via 130 to the nearest point on an edge of antipad void 125 in a corresponding metal layer, e.g., conductor 121. A diameter of antipad void 125 be defined as twice the radius of antipad void 125. Larger antipad voids 125 near pads 131 and connections 133 to traces 135 may improve electrical performance of via 130. Wider antipad voids 125 at connections 133 may reduce impedance discontinuities between vias 130 and traces 135. The mechanical performance of vias 130 (and adjacent structures in package substrate 101 and IC package 100) is improved by using smaller antipad voids 125 between these larger antipad voids 125.

The profile of antipad voids 125 with a narrower diameter near a midpoint of via 130 may be characterized as a tapered or concave void or antipad profile. With the improved mechanical performance of the tapered void profile, vias 130 may be located under IC die 110 without the need for a keepout area in a die shadow. With the improved structure of via 130 and tapered profile of antipad voids 125, IC package 100 has increased routing flexibility and I/O interconnect density (e.g., under IC die 110) and decreased package size (e.g., in an x-y plane). In some embodiments, the tapered antipad profile is employed throughout package substrate 101 and package 100. In some embodiments, the tapered antipad profile is used under die 110. In some such embodiments, the stacked or vertically aligned profile is also used in IC package 100, but not under IC die 110. In some embodiments, the tapered antipad profile is used for some vias 130 (e.g., of a certain height or taller), but not for others. In some such embodiments, the vertically aligned profile is employed for blind or buried vias 130, but not for through vias 130.

Vias 130 are substantially vertical structures between different layers 120 of IC package 100, e.g., connecting structures in different layers 120. Vias 130 have a circular cross-section (e.g., in an x-y plane) in some embodiments. For example, vias 130 may be substantially vertical, substantially cylindrical solid structures of electrically conductive material (such as copper or another metal) or tubes of such a material, e.g., with the conductive material on an interior sidewall of a hole through layers 120. Vias 130 may be other shapes. (Although the term “diameter” may be used to refer to a lateral dimension of via 130 or antipad void 125, via 130 or antipad void 125 may be shapes with non-circular cross-sections, and “diameter” may refer to a lateral dimension, such as a length or width, of such a feature.) Via 130 may have one or more pads 131, e.g., at upper and lower ends, and connections 133 to via 130 and/or pads 131. Pads 131 may be considered parts of vias 130. Vias 130, pads 131, traces 135, and conductors 121 may all be or include the same or various conductive materials. In some embodiments, one or more of these conductive structures is of copper. In other embodiments, one or more of vias 130, pads 131, traces 135, and conductors 121 are of aluminum or stainless steel. In other embodiments, one or more of these conductive structures is of another conductive material, such as a metal.

Antipad voids 125 (which may also be referred to as antipads 125) are regions in layers 120 around via 130 without any of conductors 121 in the region. While conductors 121 may be absent in antipads 125, in addition to vias 130, antipads 125 may include pads 131 and connections 133 to vias 130 and pads 131. Conductors 121 may be ground planes or other structures capable of carrying electrical current. Antipads 125, while devoid of conductors 121, may otherwise be filled with one or more insulators, such as a dielectric or other material separating conductive layers in a package substrate. In the example of FIG. 1B, antipads 125 of adjacent vias 130 overlap and form larger voids in conductors 121 that multiple vias 130 extend through.

Package substrate 101 is a planar platform and may include dielectric and metallization structures, such as conductors 121, in multiple layers 120. Substrate 101 mechanically supports and electrically couples one or more IC dies 110. Substrate 101 may be of any suitable structure and material(s), for example, any sufficiently insulating material or materials. In many embodiments, substrate 101 includes organic materials, such as a plastic. Substrate 101 may include ceramic materials, silicon, or glass. In some embodiments, substrate 101 includes fiberglass weave in an epoxy resin. Glass or silicon may have advantages over, e.g., organic substrate materials, such as higher thermal conductivity, higher strength and stiffness, and a lower propensity for absorbing moisture. IC die(s) 110 may couple to substrate 101 on an upper surface of package substrate 101, or substrate 101 may have a well or cavity in which IC die(s) 110 may be located. An upper surface of substrate 101 may be flush with IC die(s) 110, or IC die(s) 110 might extend partially beyond the upper surface of substrate 101. At least one side of substrate 101 includes substrate interconnect interfaces for coupling (e.g., soldering, direct bonding, etc.) to one or more IC dies 110. The opposite side of substrate 101 may include similar interfaces or, e.g., copper pads for socketing or solder bumps for bonding the package to a host component, such as a printed circuit board (PCB). Substrate 101 may be any host component with substrate interconnect interfaces, including an interposer, etc. Substrate 101 may couple to any other host component, such as another substrate.

IC package 100 is coupled to a system substrate 199. IC package 100 is over system substrate 199. Only a portion of substrate 199 is shown under substrate 101 as substrate 199 spans beyond the edges of FIG. 1B. IC package 100 is coupled to a power supply (not shown) through system substrate 199. IC die 110 is coupled to the power supply through system substrate 199 and, in some embodiments, package substrate 101. Substrate 199 is a planar platform and may include metallization structures and insulators. System substrate 199 mechanically supports and electrically couples one or more IC packages 100. At least one side of substrate 199 includes substrate interconnect interfaces for bonding to one or more IC packages 100. The opposite side of system substrate 199 may include similar interfaces, e.g., copper pads for socketing or otherwise coupling to package substrate 101. System substrate 199 may be any host component with substrate interconnect interfaces, such as an interposer or PCB (e.g., a motherboard). IC package 100 may be coupled to a system substrate 199 by any suitable means. In some embodiments, package 100 is coupled to substrate 199 by solder. In some embodiments, package 100 is coupled to substrate 199 by a socket (not shown) on substrate 199. For example, package 100 may have contact lands on package substrate 101 that mate with flexible pins on the socket, or rigid pins on package 100 may contact with through holes in the socket. Substrates 101, 199 may be coupled by other means.

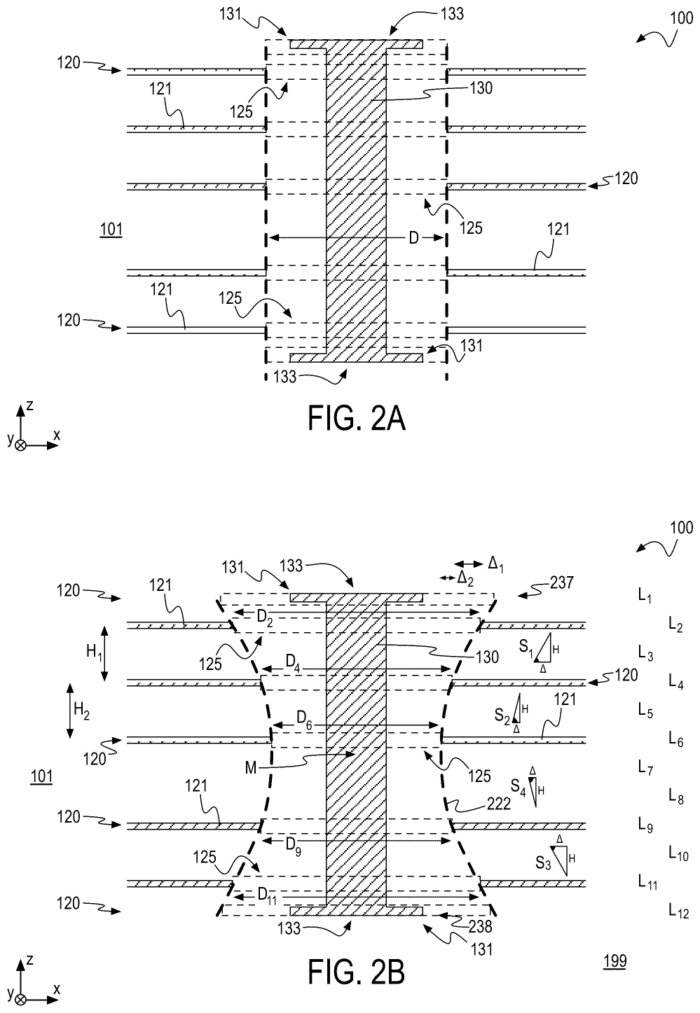

FIGS. 2A and 2B illustrate cross-sectional profile views of IC package 100 with antipad voids 125 in multiple layers 120 and via 130 through antipads 125, in accordance with some embodiments. Via 130 in package substrate 101 extends through the stack of antipads 125 in the stack of layers 120 and has connections 133 (for example, into or out of the viewing plane, in the positive or negative y direction) at pads 131. Dashed lines are used to show the edges of antipads 125. FIG. 2A shows vertically aligned antipad voids 125 around via 130, all centered on, and coaxial with, via 130 and with a same diameter D, which may be characterized as a stacked void profile. A via 130 having antipads 125 with a larger diameter D may have improved electrical performance but degraded mechanical performance (such as reduced resilience to shear vertical forces). In some embodiments, the stacked or vertically aligned profile of FIG. 2A is used in IC package 100, but not under IC die 110. In some embodiments, the vertically aligned profile of FIG. 2A is employed for only some vias 130 (e.g., of a certain height or shorter), but not for others. In some such embodiments, the vertically aligned profile of FIG. 2A is employed for blind or buried vias 130, but not for through vias 130 (or not for through vias 130 of too tall a height). Multiple antipads 125, layers 120, and conductors 121 are shown, but other antipads 125 and layers 120 may be present but not apparent where there are no conductors 121. In many embodiments, package substrate 101 has an even number of layers 120, and one of each pair of layers includes a ground plane, e.g., a substantially continuous conductor 121 spanning most of the layer 120. In some embodiments, substrate 101 has six layers 120. In some embodiments, substrate 101 has twelve layers 120. Package substrate 101 may have more or fewer layers 120.

FIG. 2B illustrates IC package 100 with antipad voids 125 in multiple layers 120 and via 130 through multiple antipads 125 collectively having a concave profile 222 in conductors 121. Antipads 125 have tapered profile 222 with offset or staggered edges wider at upper and/or lower ends 237, 238 and narrower at midpoint M. Via 130 may be through more than the twelve layers 120 shown (e.g., at layers or levels L₁ through L₁₂). Via 130 extends through at least the antipads 125 shown at layers or levels L₂, L₄, L₆, L₉, and L₁₁. Via 130 is within or extends through the antipads 125 at layers or levels L₁ and L₁₂. Via 130 has connections 133 at ends 237, 238 (at levels L₁ and L₁₂), for example, behind via 130 and into the viewing plane (e.g., in the positive y direction). Via 130 has pads 131 in levels L₁ and L₁₂ at connections 133.

Improved antipads 125 in antipad profile 222 have various diameters, such as D₂, D₄, D₆, D₉, and D₁₁. Larger diameters near pads 131, connections 133, and upper and/or lower ends 237, 238 (e.g., D₂ and D₁₁ at levels L₂ and L₁₁) may improve electrical performance of via 130, while smaller diameters (e.g., D₄, D₆, and D₉ at levels L₄, L₆, and L₉) between larger diameters may improve mechanical performance. Profile 222 of antipads 125, with a narrower diameter near midpoint M, may be characterized as a tapered void profile 222. With the improved mechanical performance of the tapered void profile 222, vias 130 may be located under the IC die 110 without the need for a keep-out area in the die shadow. IC package 100 may have increased routing flexibility and I/O interconnect density (e.g., under IC die 110) and decreased package size (for example, laterally).

Larger diameters D₂ and D₁₁ may improve electrical performance of via 130, such as signal integrity, by reducing capacitance between via 130, including pads 131, and (e.g., grounded) conductors 121. This reduced capacitance may improve impedance matching and reduce losses from mismatch and corresponding reflections, for example, by minimizing insertion loss and optimizing return losses. Smaller diameters (e.g., D₄, D₆, and D₉) away from pads 131 may improve impedance matching. Profile 222 of antipads 125 surrounding via 130 may be vertically symmetric, e.g., across midpoint M. In FIG. 2B, for example, diameters D₄ and D₉ are equal, and diameters D₂ and D₁₁ are equal. Diameter D₆, near midpoint M of via 130, is less than diameters D₄ and D₉, which are less than diameters D₂ and D₁₁.

Profile 222 of antipads 125 surrounding via 130 can be characterized as concave with slopes near ends 237, 238, flatter than slopes near midpoint M. For example, profile 222 is concave with slope S₁ between levels L₂ and La flatter than slope S₂ between levels L₄ and L₆. The slopes of profile 222 are defined by the vertical heights H between antipads 125 (and layers 120) divided by the differences or deltas Δ between the staggered ends of antipads 125. Slope S₁ is defined by height H₁ between levels L₂ and L₄, and by delta Δ₁ between the edges or boundaries of antipads 125 in levels L₂ and L₄. Slope S₂ is defined by height H₂ between levels L₄ and L₆, and by delta Δ₂ between the edges or boundaries of antipads 125 in levels L₄ and L₆. (With slopes S₁, S₂ on either side of profile 222, deltas Δ₁, Δ₂ are equal to half of the differences of diameters D₂, D₄ and of diameters D₄, D₆, respectively, or equal to the differences of the radii of antipads 125 in the case of circular antipads 125.) Delta Δ₁ is greater than delta Δ₂, so slope S₁ is less than (or flatter than) slope S₂ (assuming heights H₁, H₂ are equal). Slope S₂ being greater than slope S₁ may allow for reducing capacitance with pads 131 while providing satisfactory mechanical performance. This tapered and symmetric profile may reduce impedance discontinuities along via 130. In the example of FIG. 2B, antipad profile 222 is vertically symmetric about midpoint M, so the slope S₃ under level L₉, for example, is similarly flatter than the slope S₄ over level L₉. With slopes S₂. S₄, adjacent midpoint M greater than flatter slopes S₁, S₃ adjacent ends 237, 238, profile 222 is concave in addition to being tapered.

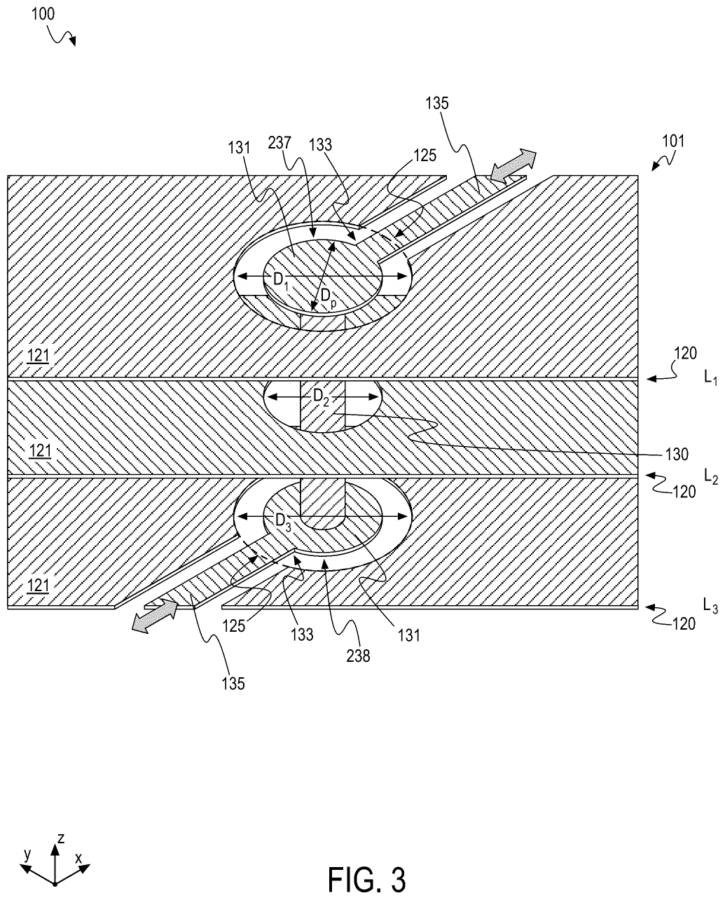

FIG. 3 illustrates an isometric view of IC package 100 having traces 135 with connections 133 to, and antipads 125 around, via 130 in a tapered antipad profile, in accordance with some embodiments, in accordance with some embodiments. Traces 135 are within layers 120 of conductors 121 in substrate 101. The edges of conductors 121 may be defined by keepout areas around traces 135. Connections 133 to via 130 may be in layers 120 over or under a sheet of conductor 121 (e.g., a ground plane), but connections 133 may be in a same layers 120 with one or more conductors 121. Via 130 has connections 133 to traces 135 at ends 237, 238 in layers 120 at levels L₁, L₃. Via 130 is within antipad 125 in layer 120 at level L₃, through antipad 125 in layer 120 at level L₂ (over level L₃), and within antipad 125 in layer 120 at level L₁ (over level L₂). Diameters D₁ and D₃ of antipads 125 at levels L₁, L₃ are both greater than diameter D₂ of antipad 125 at level L₂. Diameters D₁ and D₃ of antipads 125 at levels L₁, L₃ are equal. Diameter D₂ of antipad 125 at level L₂ is equal to diameter D_{P} of pads 131 at levels L₁, L₃. In some embodiments, diameter D₂ is greater than diameter D_{P}. In some embodiments, diameter D_{P} is greater than diameter D₂.

Although package substrates 101 may often have six or twelve layers 120, substrates 101 may have more or fewer layers 120. Also, however many layers 120 substrate 101 has, a concave or tapered profile of antipads 125 may be employed for any via 130 with enough levels or layers 120, whether or not via 130 spans all of the layers 120 of substrate 101. Via 130 may be between layers 120 in a shorter stack of layers 120 or between only some layers 120 in a stack having many more layers 120.

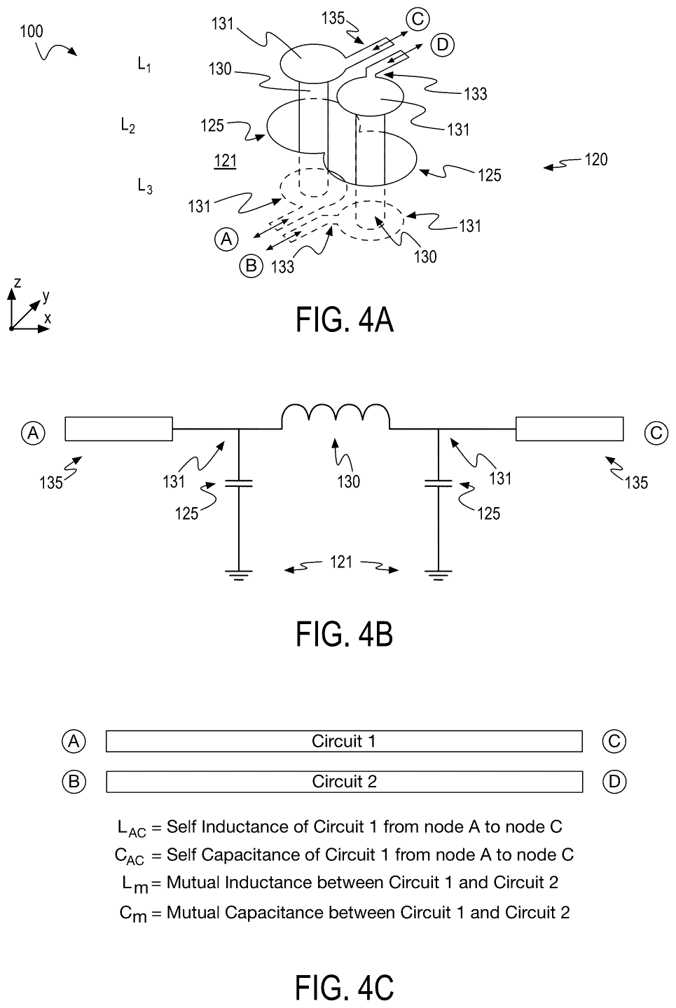

FIGS. 4A, 4B, and 4C illustrate isometric and schematic views of vias 130, antipads 125, and adjacent structures, in accordance with some embodiments. In many embodiments, some of vias 130 and traces 135 are configured in this or a similar paired configuration, such as a differential pair, which may be beneficial in high-speed data signaling or other applications. FIG. 4A shows two adjacent vias 130 in and through three layers 120. In middle layer 120 at layer or level L₂, conductor 121 is a ground plane. Antipad void 125 in conductor 121 is around vias 130. The single, large antipad void 125 may be characterized as a union of two smaller, circular antipad voids 125 around the separate vias 130. Vias 130 have at pads 131 (at levels L₁, L₃) and connections 133 to traces 135 and nodes A, B in L₃ and traces 135 and nodes C. D in L₁.

FIG. 4B illustrates a proposed electrical model of one of vias 130 in FIG. 4A. At high enough frequencies, a conductive via 130 may be substantially inductive, which is how via 130 is represented in FIG. 4B. Capacitors are connected on either side of via 130, between the ground of conductors 121 and each junction of traces 135 to via 130. These capacitance values may vary with various dimensions (as well as other parameters). While there is some capacitance between the shaft of via 130 and conductor 121, this capacitance may be much smaller than the capacitances between pads 131 and conductor 121 for typical sizes of pads 131 and for typical heights between pads 131 and conductor 121, especially when antipads 125 (between via 130 and conductor 121) are sufficiently large. The capacitors, as shown, may be dominated by the capacitances between pads 131 and the ground of conductors 121 (across antipad voids 125). These capacitance values will be greater for smaller antipads 125 (between conductors 121 and via 130 or pads 131) or, similarly, if pads 131 are larger and overhang more (or more closely approach) conductor 121. These capacitance values will also be greater for conductors 121 closer to pads 131. In models of vias 130 through multiple layers 120 of conductors 121, capacitances between large pads 131 and various conductors 121 will be smaller for conductors 121 with larger heights between pads 131 and conductors 121. For example, capacitances between pads 131 or traces 135 and conductors 121 with narrower antipads 125 can be minimized by larger heights separating pads 131 or traces 135 and conductors 121. Nodes A, C are at either end of the proposed circuit with the series inductance between nodes A, C and shunt capacitances to ground on each end of the inductor.

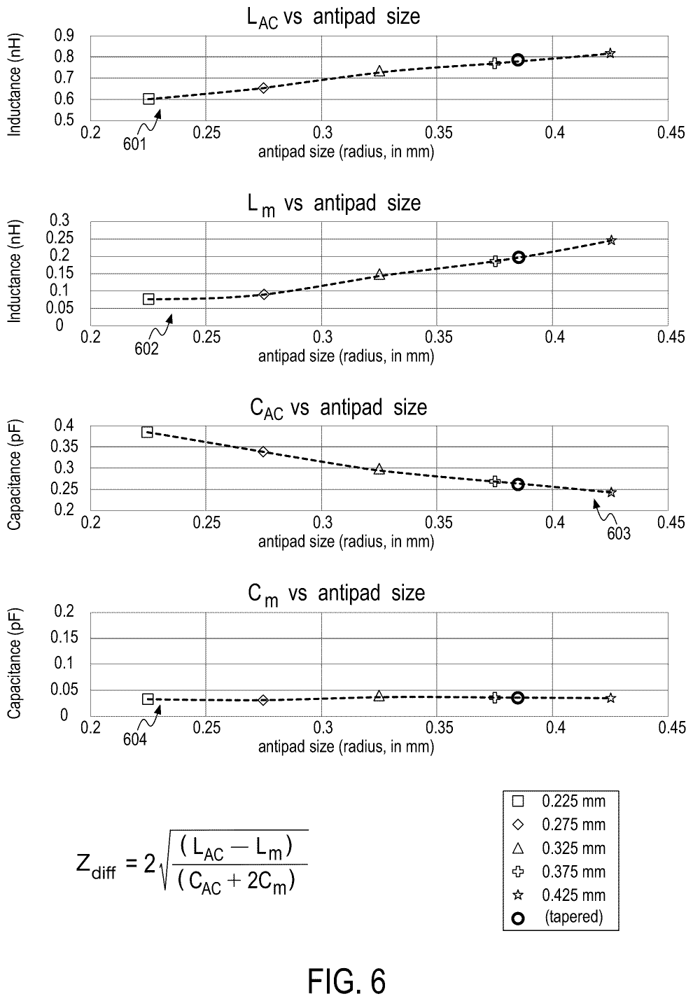

FIG. 4C shows the proposed electrical circuit of FIG. 4B (as Circuit 1 between nodes A, C) alongside a similar Circuit 2 (between nodes B, D). L_{AC} and C_{AC} are defined as the self-inductance and -capacitance, respectively, between nodes A, C within Circuit 1. Lₘ and Cₘ are defined as the mutual inductance and capacitance, respectively, between Circuits 1, 2. As is described elsewhere herein (e.g., at least at FIG. 6), decreasing the capacitance terms increases the differential impedance in this paired configuration. However, changes to structure dimensions may influence other parameters, which can also affect the differential impedance.

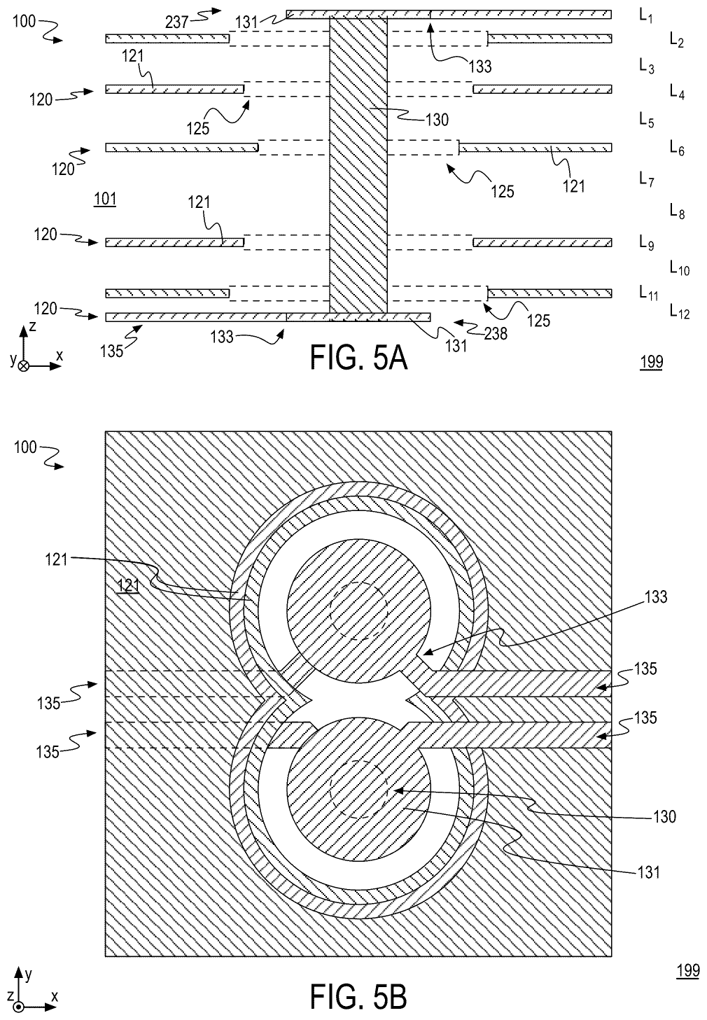

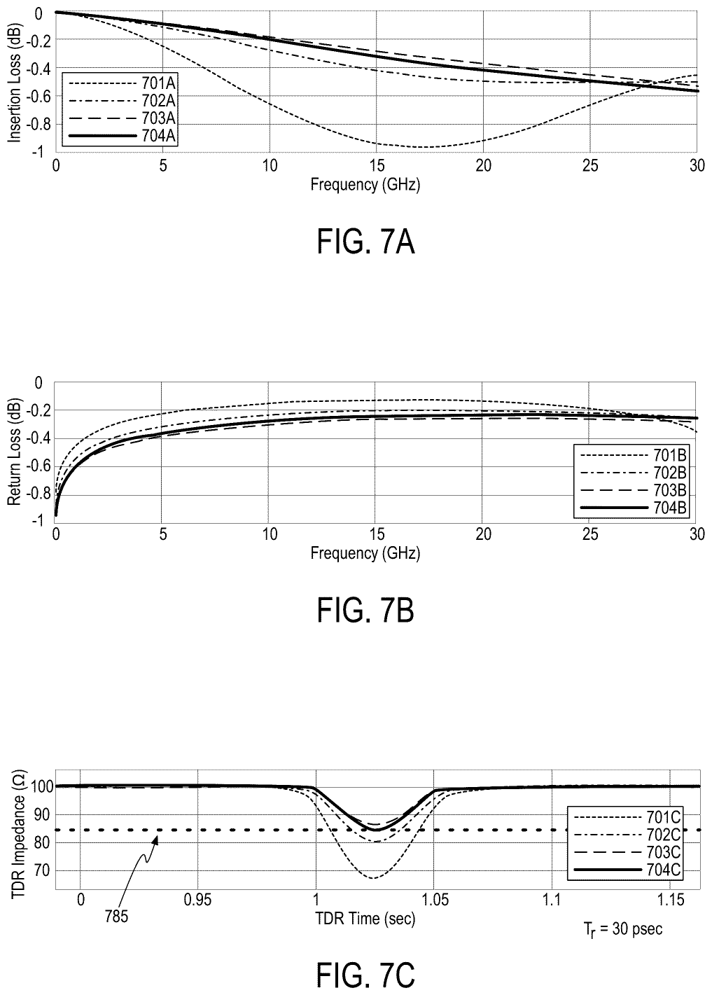

FIGS. 5A and 5B illustrate a cross-sectional profile and plan views of IC package 100 with antipads 125 in multiple layers 120 and vias 130 through antipads 125, in accordance with some embodiments. The embodiments of FIGS. 5A and 5B, as well as similar structures with different dimensions, were modeled similarly to the description in at least FIGS. 4B and 4C. The results of the modeling and simulation is described elsewhere herein (e.g., at least at FIGS. 6-7C). The similar structures with different dimensions used for comparison to the tapered profile of the embodiments of FIGS. 5A and 5B also have conductors 121 in layers 120 at levels L₂, L₄, L₆, L₉, and L₁₁, but employ stacked or vertically aligned antipad profiles.

FIG. 5A shows a cross-sectional profile view of IC package 100 and via 130 similar to that described in FIG. 2B. Via 130 extends through multiple antipads 125 and multiple layers 120, including conductors 121 in layers 120 at levels L₂, L₄, L₆, L₉, and L₁₁. Via 130 has connections 133 to traces 135 at pads 131 in layers 120 at levels L₁ and L₁₂. Antipads 125 have a tapered profile around via 130. A second via 130 and stack of antipads 125 are behind the visible via 130 in FIG. 5A. The second via 130 and stack of antipads 125 have the same dimensions as the visible via 130. The second via 130 has connections 133 to traces 135 at pads 131 in layers 120 at levels L₁ and L₁₂ as shown in FIG. 5B.

FIG. 5B illustrates a plan view of IC package 100 with vias 130 through multiple layers 120 of antipads and conductors 121. Vias 130 are parallel and each via 130 has a stack of antipads coaxial with that via 130. The two circular (or disc) antipads at a given level overlap to form a larger, joined antipad in which conductors 121 are absent. The extent of antipad voids in conductors 121 in levels L₂, L₄, and L₆ are apparent from the edges of conductors 121 around vias 130 and pads 131. In some embodiments, vias 130 are spaced further apart or their antipads have sufficiently short diameters (in at least one layer 120) such that the antipads do not overlap, and one or more conductors 121 are between vias 130 (in at least one layer 120). Pads 131 and traces 135 in level L₁ are over conductor 121 in level L₂. Conductor 121 in level L₆ most closely approaches pads 131 (though levels below) and vias 130. Conductor 121 in level L₄ is over conductor 121 in level L₆ and between conductors 121 at levels L₂ and L₆. Traces 135 in level L₁₂ are under conductors 121 in levels L₉ and L₁₁, which are both obscured by conductor 121 at level L₆.

Pad 131 of one via 130 may be in antipad 125 of another via 130. In some embodiments, keepout exceptions are made for conductors associated with paired adjacent vias 130 (e.g., pads 131 in the antipad of other via 130). In some embodiments, larger antipads are used in layers 120 with ground plane conductors 121 than in other layers 120, e.g., layers 120 with pads 131.

FIG. 6 is a plurality of plots 601, 602, 603, 604 of modeled data comparing various circuit parameters for vias 130 in a differential-pair configuration, in accordance with some embodiments. Two vias 130 were modeled using the structures described at FIGS. 5A and 5B, as well as similar structures, but with stacked or vertically aligned antipads 125. The simulated data is plotted in FIG. 6 by antipad size. (Note that antipad sizes use radii for these circular antipads 125 around and coaxial with cylindrical vias 130.) Note that in all cases, pads 131 have radii of 0.225 mm. A key for plots 601-604 is provided near the bottom of FIG. 6.

The circuit parameters for paired vias 130 with an improved, tapered antipad profile are plotted with a circle at antipad size of 0.385 mm, which is the weighted average of the various antipads 125 in the structure described at FIGS. 5A and 5B. The widest antipads 125 at levels L₂ and L₁₁ have radii of 0.425 mm. The narrowest antipad 125 at level L₆ has a radius of 0.325 mm. The intervening antipads 125 at levels L₄ and L₉ have radii of 0.375 mm.

The circuit parameters for paired vias 130 with a vertically aligned antipad profile are plotted with the other various shapes at their respective antipad sizes. Each (non-circle) shape represents paired vias 130 with stacks of antipads 125 having equal diameters (and radii). Antipads 125 at levels L₂, L₄, L₆, L₉, and L₁₁ have radii ranging from 0.225 mm to 0.425 mm. For example, the data represented by squares are for two paired vias 130 with two stacks of antipads 125 having equal radii. In the case of the data represented by squares, half of the antipads 125 are coaxial with a first via 130 and the other half of the antipads 125 are coaxial with a second via 130, and all antipads 125 (e.g., at levels L₂, L₄, L₆, L₉, and L₁₁) have radii equal to 0.225 mm. Notably, in the case of the data represented by squares (radii equal to 0.225 mm) and diamonds (radii equal to 0.275 mm), vias 130 are spaced such that their respective antipads 125 do not overlap and conductors 121 (e.g., at each of levels L₂, L₄, L₆, L₉, and L₁₁) connect between vias 130.

A formula for differential impedance Z_{diff} is provided near the bottom of FIG. 6. To increase differential impedance Z_{diff}, the numerator under the radical symbol can be increased and/or the denominator under the radical can be decreased. As such, to increase differential impedance Z_{diff}, the self-inductance L_{AC}, self-capacitance C_{AC}, and/or mutual capacitance Cₘ can be increased and/or the mutual inductance Lₘ can be decreased. Given plots 601-604 and what they show of the constituent parameters for the various modeled via pairs, differential impedance Z_{diff} should be maximized for the star data (representing stacked antipads 125 with radii of 0.425 mm). However, the tapered antipad profile (represented by the circle data) provides superior mechanical performance with nearly optimal electrical performance approximating that of the star data in plots 601-604.

Plots 601, 602 show self-inductance L_{AC} and mutual inductance Lₘ, respectively, of the various modeled structures. Self-inductance L_{AC} is greater than mutual inductance Lₘ, and their difference is the numerator, so increasing self-inductance L_{AC} or decreasing mutual inductance Lₘ will increase differential impedance Z_{diff}. However, although both inductances increase with antipad size, self-inductance L_{AC} and mutual inductance Lₘ increase more or less together, and their difference is relatively constant across the various antipad radii.

Plots 603, 604 show self-capacitance C_{AC} and mutual capacitance Cₘ, respectively, of the various modeled structures. Increasing either or both of self-capacitance C_{AC} and mutual capacitance Cₘ will increase differential impedance Z_{diff}. Plot 604 shows that mutual capacitance Cₘ is relatively constant across the various antipad radii.

Plot 603 show that, for the via pairs with vertically aligned antipads, self-capacitance C_{AC} decreases significantly as antipad radii increases. This is much as has been described elsewhere herein (e.g., at least at FIG. 4B). As antipad sizes increase, the spacing between antipads 125 and adjacent grounded conductors 121 also increase, and the shunt self-capacitance C_{AC} between nodes A, C decreases. Plot 603 also shows that self-capacitance C_{AC} is appropriately low for the via pairs with the tapered antipad profile. Although the narrowest antipad 125 (at level L₆) has a radius of 0.325 mm (and intervening antipads 125 at levels L₄ and L₉ have radii of 0.375 mm), grounded conductors 121 are sufficiently far away from pads 131, and self-capacitance C_{AC} is almost as low as for the via pairs with antipad radii of 0.425 mm.

FIGS. 7A, 7B, and 7C illustrate plots 701, 702, 703, 704 for comparison of electrical performances of various modeled vias 130, in accordance with some embodiments. Plots 704 show the electrical performance of the embodiment with antipad voids 125 having tapered antipad profiles around paired vias 130, as described in FIGS. 5A and 5B, and correspond to the data represented by circles in the plots of FIG. 6. Plots 701, 702, 703 show the electrical performance of paired vias 130 with vertically aligned antipads 125 with radii of 0.225, 0.325, and 0.425 mm, respectively, and correspond to the data represented by squares, triangles, and stars in the plots of FIG. 6. The compared electrical performances illustrated in plots 701-704 show best impedance matching by vertically aligned antipads 125 with radii of 0.425 mm (represented by plots 703), but with that impedance matching nearly matched by the tapered antipad profiles represented by plots 704.

FIG. 7A shows insertion losses for the four modeled structures over a range of frequencies. Plot 701A corresponds to a structure with the narrowest, stacked void profile (with radii of 0.225 mm) and generally shows the worst performance, for example, much more loss across a wide range of frequencies. Plot 703A corresponds to a structure with the widest, stacked void profile (with radii of 0.425 mm) and generally shows the best performance, with the least loss at most frequencies. Plot 702A corresponds to a structure with an intermediate stacked void profile (with radii of 0.325 mm) and generally shows performance between the best and worst of plots 703A, 701A.

Plot 704 shows performance generally better than plots 701A, 702A and substantially similar to that of plot 703A, particularly at 10 GHz and below. Plot 704A is for a structure with a tapered void profile having a widest diameter at the upper and lower ends corresponding to the structure of plot 703A and a narrow diameter at the midpoint corresponding to the structure of plot 702A.

FIG. 7B illustrates return losses for the same four modeled structures and over the same range of frequencies. Plot 701B generally shows the worst performance, corresponding to larger impedance mismatches and reflections over most frequencies. Plot 703B generally shows the smallest reflected signal strength at most frequencies. Plot 702B shows an intermediate performance. Plot 704B shows the performance of the tapered void profile generally tracking with that of plot 703B.

FIG. 7C shows the impedances for the same four structures as modeled responses to a time-domain reflectometer (TDR) pulse with a pulse rise time of 30 ps. Plot 704C for the tapered void profile shows the best performance with an impedance with smooth transitions along the via without substantial discontinuities and matched to the target impedance 85Ω (indicated by dashed line 785). Impedances can be further tuned, e.g., to other values or with a different profile along the via, by adjusting various dimensions along the via, such as pad or antipad diameters or heights between conductor layers.

Plots 701-704 of FIGS. 7A-7C generally show the tapered void profile performing nearly as well as, or better than, the widest stack void profile, which sacrifices mechanical performance for incremental electrical improvements (if that).

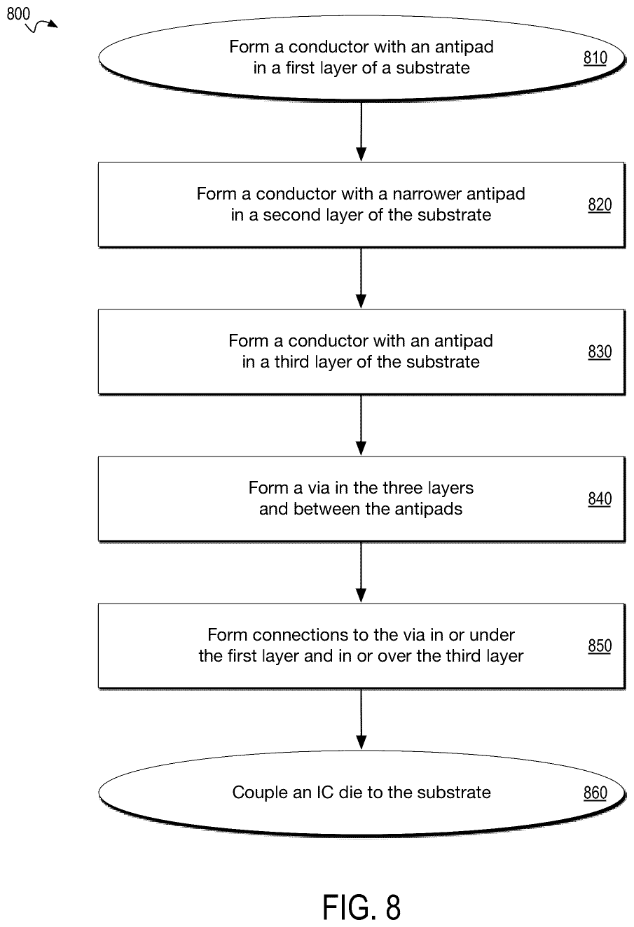

FIG. 8 is a flow chart of methods 800 for forming a via with a tapered antipad void profile, in accordance with some embodiments. Methods 800 include operations 810-860. Some operations shown in FIG. 8 are optional. Additional operations may be included. FIG. 8 shows an example sequence, but the operations can be done in other orders as well, and some operations may be omitted. Some operations can also be performed multiple times before other operations are performed. For example, more layers can be formed with antipads, or multiple vias may be formed, such as paired vias with overlapping antipads. Some operations may be included within other operations so that the number of operations illustrated FIG. 8 is not a limitation of the methods 800.

Multiple layers of conductors may be formed in a substrate with antipad voids of varying dimensions formed in the conductors. A narrowest antipad may be formed in a conductor between other conductors with wider antipads. The antipad voids may be formed in already formed conductors. For example, a hole may be etched or bored through a substantially continuous conductor layer, or some conductive material may be etched away in the desired antipad region. The conductors may be initially formed with antipad voids. For example, the antipad voids may be keepout regions automatically kept absent of conductors, and then a conductor layer may be formed with an antipad void in the conductors as-formed. A via may be formed in and through the antipads in multiple layers. Connections to the via may be made, for example, at the top and bottom of the via. The connections may be in one or more of the conductor layers with antipad voids or over and under these conductor layers. An IC die may be coupled to the substrate, including over the via.

Methods 800 begin with forming a first conductor having a first antipad in a first layer of a substrate at operation 810. The layer and conductor may be formed by any suitable means and of any suitable materials. In some embodiments, the layer and conductor are formed over a received substrate. In some embodiments, the first layer will be a substrate for forming subsequent layers over the first layer, e.g., in a single build-up direction or on both sides of, and directions from, the first-layer substrate. In many embodiments, the first layer and at least some subsequent layers are formed separately and assembled into a stack of layers. In many embodiments, the first layer and subsequent layers are formed in pairs of layers and assembled into a stack with an even number of layers. In some embodiments, layers are added to both sides of a first-layer substrate such that the eventual stack of layers has an even number of layers. In some embodiments, one, some, or all of the pairs include one layer that is mostly conductive material (such as copper or another metal), e.g., as a ground plane, and the other layer has some conductive material formed into various structures, such as conductive traces. For example, a substrate of a sufficiently insulating material (such as plastic, glass, fiberglass weave impregnated with resin, etc.) may have conductive material formed (e.g., deposited, plated, printed, etc.) on both sides of the substrate.

The conductive material may be formed using any suitable means. In many embodiments, photolithography is used to pattern various structures of conductive material. In some embodiments, the conductive material is deposited in desired pattern using a photomask or film. In many embodiments, the conductive material is deposited as a foil or film or other complete layer, and photolithographic mask is patterned onto the conductive layer before removing any conductive material not masked. In some embodiments, conductive material is deposited in complete layers on both sides of the substrate, and much of the conductive material is removed from one side (e.g., to form conductive traces, etc.) while moving little or no conductive material from the other side (e.g., for a ground plane).

In this way (or other ways), an antipad (or gap, hole, cavity, etc.) may be formed in a conductor. For example, a circular void or antipad may be formed in a mostly solid layer of copper (or other conductive material) with the center of the antipad (and the antipad's diameter) on a planned axis for a via to be subsequently formed. The axis may also be the planned center for other antipads in other, subsequent layers.

Methods 800 continue at operation 820 with forming a second conductor having a second antipad in a second layer. The second conductor and second layer may be formed before, concurrently with, or after the first conductor and first layer are formed, as described at operation 810, such that the first layer need not be the layer first formed. A second layer may be formed over (or under) the first layer or as one of a pair of layers with the first layer. In many embodiments, the second conductor and second layer are formed in a similar manner as (and either before, concurrently with, or after) the first conductor and first layer, such as in pairs of layers. The first and second layers may then be assembled (e.g., after careful alignment). In some such embodiments, the first and second layers are assembled each from separate pairs of layers, with each pair of layers sharing an insulating substrate between the layers. When assembling pairs of layers, two layers (each on separate substrates) may be contacted together (e.g., and bonded) or the two layers may be brought together with an insulating substrate or layer (without conductive material formed on any surface) between the two layers and substrates.

A second antipad may be formed in the second conductor similar to the first antipad in the first conductor (e.g., with positive or negative photoresist or photolithography). The second antipad may have a second diameter, shorter than the diameter of the first antipad, but centered on (e.g., bisected by) the same axis, such that the second antipad will be smaller than, but coaxial with, the first antipad (and that both antipads will be centered on the eventual via). Again, the layers should be carefully aligned before assembly to ensure the antipads (and eventual via) are coaxial.

Methods 800 continue with forming a third conductor having a third antipad in a third layer at operation 830. The third conductor and third layer may be formed before, concurrently with, or after the first and second conductors and first and second layers are formed, as described at operations 810, 820. In many embodiments, the third conductor and third layer are assembled in a stack of an even number of layers, for example, with three ground planes and three other layers with conductive structures formed on the layers. The third conductor and third layer may be formed over the second conductor and second layer such that the second layer is between the first and third layers. In embodiments with the first layer over the second layer, the second conductor and second layer may be over the third conductor and third layer such that the second layer is between the first and third layers.

A third antipad may be formed in the third conductor similar to the first and second antipads in the first and second conductors. The third antipad may have a third diameter, equal to the diameter of the first antipad and centered on the same axis, such that the third antipad will be coaxial with the first and second antipads (and the eventual via). In this way, the smaller second antipad will be coaxial with and between the first and third antipads, and the three antipads will collectively form a stack of antipads with a tapered antipad profile (around the axis and eventual via).

In some embodiments, one of the layers (or pairs of layers) may be a substrate that other layers are built up from, and that substrate may be the layer at the midpoint of the stack of layers. In some such embodiments, that substrate layer may have a middle and smallest antipad of the stack of antipads, and that substrate layer may be the second layer between the first and third layers and having the second antipad with the second, shorter diameter.

In some embodiments, methods 800 include forming a fourth conductor having a fourth antipad in a fourth layer. The fourth conductor and fourth layer may be formed much as other conductors and layers, but should be included in the stack of layers during assembly such that the fourth layer is between the first and third layers, and the second layer is at a midpoint of the via or at least between the fourth layer and the midpoint of the via.

The fourth antipad may also may be formed much as other antipads (e.g., patterned as a void in the fourth conductor in the fourth layer, and centered on the axis, coaxial with the other antipads). The fourth antipad should also be formed of the proper size to maintain the tapered antipad profile. With the fourth antipad in the fourth layer (between the second antipad and either of the first and third diameters), the fourth antipad diameter is greater than the second diameter and shorter than the first and third diameters. Like the fourth antipad, the fourth antipad diameter is centered on the axis such that the fourth antipad will be coaxial with the via and the other antipads.

In some embodiments, methods 800 include forming a fifth conductor having a fifth antipad in a fifth layer. The fifth conductor and fifth layer may be formed much as other conductors and layers, but should be included in the stack of layers during assembly such that the fifth layer is between the first and third layers, and the second layer is between the fourth and fifth layers.

The fifth antipad may also may be formed much as other antipads (e.g., patterned as a void in the fifth conductor in the fifth layer, and centered on the axis, coaxial with the other antipads). The fifth antipad should also be formed of the proper size to maintain the tapered antipad profile. With the fifth antipad in the fifth layer (between the second antipad and either of the first and third diameters), the fifth antipad diameter is greater than the second diameter and shorter than the first and third diameters. In some embodiments, the fifth antipad diameter is equal to the fourth antipad diameter. Like the fifth antipad, the fifth antipad diameter is centered on (and bisected by) the axis such that the fifth antipad will be coaxial with the via and the other antipads.

Methods 800 continue at operation 840 with forming a via on the axis and in at least the first, second, and third layers. The via may be formed by any suitable means. For example, the via may be formed by forming (e.g., boring or etching) a hole in or through (at least) the first, second, and third layers. In some embodiments, the hole is formed by drilling through the layers. In some embodiments, a laser bores the hole. A metal (such as copper, etc.) or another conductive material may be formed in the hole. The hole may be filled with the conductive material, or the conductive material may be deposited (e.g., plated) on a sidewall of the hole formed through the layers. The hole and subsequent via should be formed on the axis and so through the antipads, the voids in the conductors.

The via may go through additional layers, which may be between the first and third layers. The via may go through first, second, and third layers, as well as layers over and under the first, second, and third layers, e.g., to connect structures (such as traces) in the layers over and under the first, second, and third layers. There may be other layers that the via does not go through. For example, a via may connect structures (such as traces) in a middle and a top layer, a middle and a bottom layer, or two buried layers. In some embodiments, a via may be formed before the entire stack of layers is assembled.

Methods 800 continue with forming first and second connections to the via at operation 850. The connections may be formed by any suitable means and with any suitable materials. The connections may be by conductive traces to conductive pads centered on the via. In many embodiments, the connections are made by forming the via. For example, the layers may be formed and assembled with conductive traces and pads already on some layers when the via hole is formed through the layers between two pads. Conductive material (such as copper) that is plated (or otherwise deposited) in or on the hole may also then form connections (e.g., electrical connections) to the (two or more) pads and traces. In some embodiments, a pad is formed over the via and connecting the via to a conductive trace. Connections may be formed by other means.

The connections may be between the first and third layers or between the first or third layer and a layer under the first layer or over the third layer. For example, the first connection may be in or under the first layer, and the second connection may be in or over the third layer. The via hole may be formed before the layer are fully assembled. In some embodiments, the via hole may be formed as multiple holes in multiple layers before the holes and layers are aligned and assembled.

Methods 800 continue at operation 860 with coupling an IC die to the substrate. The substrate formed (or added to) by forming or assembling the layers may be an IC package substrate for mounting or supporting one or more IC dies. The tapered antipad profile may enable a higher density of I/O interconnects or of routing in the IC package. The IC die and package substrate may be coupled by any suitable means. In some embodiments, the die and substrate are direct bonded. In some embodiments, the die is soldered to the package substrate. In some embodiments, the tapered antipad profile enables the placement of the IC die directly over vias in the package substrate. In some such embodiments, the IC die is coupled over a via with a tapered antipad profile.

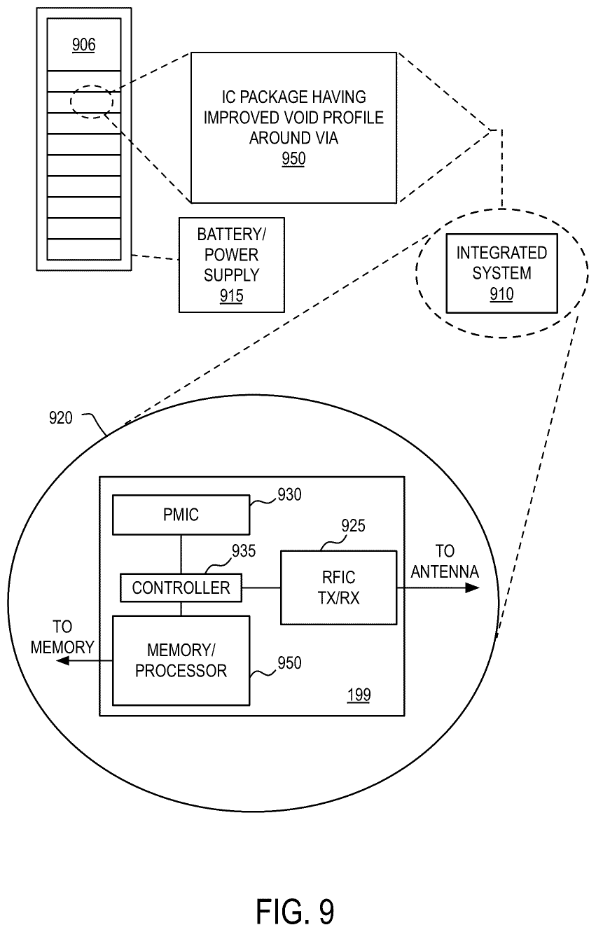

FIG. 9 illustrates a diagram of an example data server machine 906 employing an IC device having a via with a tapered antipad profile, in accordance with some embodiments. Server machine 906 may be any commercial server, for example, including any number of high-performance computing platforms disposed within a rack and networked together for electronic data processing, which in the exemplary embodiment includes one or more devices 950 having a via with a tapered antipad profile.

Also as shown, server machine 906 includes a battery and/or power supply 915 to provide power to devices 950, and to provide, in some embodiments, power delivery functions such as power regulation. Devices 950 may be deployed as part of a package-level integrated system 910. Integrated system 910 is further illustrated in the expanded view 920. In the exemplary embodiment, devices 950 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 950 is a microprocessor including a static RAM (SRAM) cache memory. As shown, device 950 may be an IC device having a via with a tapered antipad profile, as discussed herein. Device 950 may be further coupled to (e.g., communicatively coupled to) a board, an interposer, or a substrate 199 along with, one or more of a power management IC (PMIC) 930, RF (wireless) IC (RFIC) 925 including a wideband RF (wireless) transmitter and/or receiver (TX/RX) (e.g., including a digital baseband and an analog front end module further includes a power amplifier on a transmit path and a low noise amplifier on a receive path), and a controller 935 thereof. In some embodiments, RFIC 925, PMIC 930, controller 935, and device 950 include a via with a tapered antipad profile.

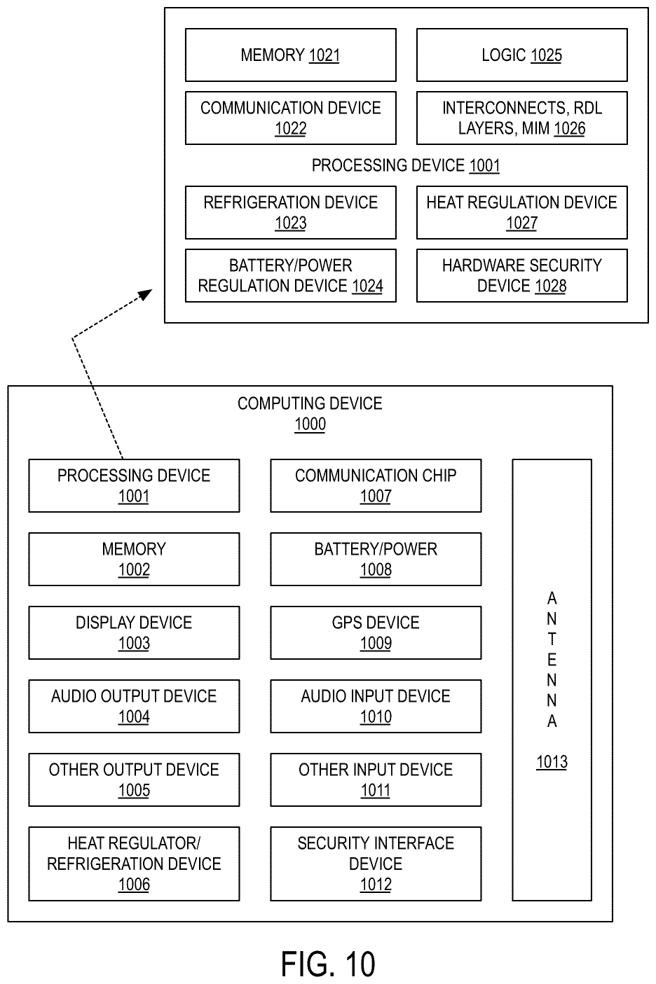

FIG. 10 is a block diagram of an example computing device 1000, in accordance with some embodiments. For example, one or more components of computing device 1000 may include any of the devices or structures discussed herein. A number of components are illustrated in FIG. 10 as being included in computing device 1000, but any one or more of these components may be omitted or duplicated, as suitable for the application. In some embodiments, some or all of the components included in computing device 1000 may be attached to one or more printed circuit boards (e.g., a motherboard). In some embodiments, various ones of these components may be fabricated onto a single system-on-a-chip (SoC) die. Additionally, in various embodiments, computing device 1000 may not include one or more of the components illustrated in FIG. 10, but computing device 1000 may include interface circuitry for coupling to the one or more components. For example, computing device 1000 may not include a display device 1003, but may include display device interface circuitry (e.g., a connector and driver circuitry) to which display device 1003 may be coupled. In another set of examples, computing device 1000 may not include an audio output device 1004, other output device 1005, global positioning system (GPS) device 1009, audio input device 1010, or other input device 1011, but may include audio output device interface circuitry, other output device interface circuitry, GPS device interface circuitry, audio input device interface circuitry, audio input device interface circuitry, to which audio output device 1004, other output device 1005, GPS device 1009, audio input device 1010, or other input device 1011 may be coupled.

Computing device 1000 may include a processing device 1001 (e.g., one or more processing devices). As used herein, the term “processing device” or “processor” indicates a device that processes electronic data from registers and/or memory to transform that electronic data into other electronic data that may be stored in registers and/or memory. Processing device 1001 may include a memory 1021, a communication device 1022, a refrigeration device 1023, a battery/power regulation device 1024, logic 1025, interconnects 1026 (i.e., optionally including redistribution layers (RDL) or metal-insulator-metal (MIM) devices), a heat regulation device 1027, and a hardware security device 1028.

Processing device 1001 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 1000 may include a memory 1002, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1002 includes memory that shares a die with processing device 1001. This memory may be used as cache memory and may include embedded dynamic random-access memory (eDRAM) or spin transfer torque magnetic random-access memory (STT-MRAM).

Computing device 1000 may include a heat regulation/refrigeration device 1006. Heat regulation/refrigeration device 1006 may maintain processing device 1001 (and/or other components of computing device 1000) at a predetermined low temperature during operation.

In some embodiments, computing device 1000 may include a communication chip 1007 (e.g., one or more communication chips). For example, the communication chip 1007 may be configured for managing wireless communications for the transfer of data to and from computing device 1000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 1007 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1007 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1007 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1007 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1007 may operate in accordance with other wireless protocols in other embodiments. Computing device 1000 may include an antenna 1013 to facilitate wireless communications and/or to receive other wireless communications (such as AM or FM radio transmissions).

In some embodiments, communication chip 1007 may manage wired communications, such as electrical, optical, or any other suitable communication protocols (e.g., the Ethernet). As noted above, communication chip 1007 may include multiple communication chips. For instance, a first communication chip 1007 may be dedicated to shorter-range wireless communications such as Wi-Fi or Bluetooth, and a second communication chip 1007 may be dedicated to longer-range wireless communications such as GPS, EDGE, GPRS, CDMA, WiMAX, LTE, EV-DO, or others. In some embodiments, a first communication chip 1007 may be dedicated to wireless communications, and a second communication chip 1007 may be dedicated to wired communications.

Computing device 1000 may include battery/power circuitry 1008. Battery/power circuitry 1008 may include one or more energy storage devices (e.g., batteries or capacitors) and/or circuitry for coupling components of computing device 1000 to an energy source separate from computing device 1000 (e.g., AC line power).

Computing device 1000 may include a display device 1003 (or corresponding interface circuitry, as discussed above). Display device 1003 may include any visual indicators, such as a heads-up display, a computer monitor, a projector, a touchscreen display, a liquid crystal display (LCD), a light-emitting diode display, or a flat panel display, for example.

Computing device 1000 may include an audio output device 1004 (or corresponding interface circuitry, as discussed above). Audio output device 1004 may include any device that generates an audible indicator, such as speakers, headsets, or earbuds, for example.

Computing device 1000 may include an audio input device 1010 (or corresponding interface circuitry, as discussed above). Audio input device 1010 may include any device that generates a signal representative of a sound, such as microphones, microphone arrays, or digital instruments (e.g., instruments having a musical instrument digital interface (MIDI) output).

Computing device 1000 may include a GPS device 1009 (or corresponding interface circuitry, as discussed above). GPS device 1009 may be in communication with a satellite-based system and may receive a location of computing device 1000, as known in the art.

Computing device 1000 may include other output device 1005 (or corresponding interface circuitry, as discussed above). Examples of the other output device 1005 may include an audio codec, a video codec, a printer, a wired or wireless transmitter for providing information to other devices, or an additional storage device.

Computing device 1000 may include other input device 1011 (or corresponding interface circuitry, as discussed above). Examples of the other input device 1011 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1000 may include a security interface device 1012. Security interface device 1012 may include any device that provides security measures for computing device 1000 such as intrusion detection, biometric validation, security encode or decode, access list management, malware detection, or spyware detection.

Computing device 1000, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-10. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a package substrate, including a plurality of metal layers and a plurality of voids, and an integrated circuit (IC) die on the package substrate, wherein the package substrate includes a first metal layer having a first void, the first void having a first radius, a second metal layer having a second void, the second metal layer over the first metal layer, the second void having a second radius smaller than the first radius, a third metal layer having a third void, the third metal layer over the second metal layer, the third void having a third radius larger than the second radius, and a metal via within, and extending through at least one of, the first, second, and third voids.

In one or more second embodiments, further to the first embodiments, a first connection to the metal via is in or under the first metal layer, and a second connection to the metal via is in or over the third metal layer.

In one or more third embodiments, further to the first or second embodiments, the metal via includes a first pad at the first connection or a second pad at the second connection.

In one or more fourth embodiments, further to the first through third embodiments, the first radius is substantially equal to the third radius.

In one or more fifth embodiments, further to the first through fourth embodiments, a fourth void at the metal via in a fourth metal layer has a fourth radius, the fourth metal layer is between the first and third metal layers, the first and third radii are greater than the fourth radius, and the fourth radius is greater than the second radius.

In one or more sixth embodiments, further to the first through fifth embodiments, a fifth void at the metal via in a fifth metal layer has a fifth radius, the fifth metal layer is between the first and third metal layers, the second metal layer is between the fourth and fifth metal layers, the first and third radii are greater than the fifth radius, and the fifth radius is greater than the second radius.

In one or more seventh embodiments, further to the first through sixth embodiments, a void profile around the metal via has a first slope adjacent an end of the metal via, the void profile has a second slope adjacent a midpoint of the metal via, and the second slope is greater than the first slope.

In one or more eighth embodiments, further to the first through seventh embodiments, the plurality of metal layers includes at least one pair of the metal layers above or below a midpoint of the metal via, each such pair includes a distal metal layer further from the midpoint and an intervening metal layer nearer to the midpoint, and the distal metal layer includes a distal void having a radius greater than a radius of an intervening void in the intervening metal layer.

In one or more ninth embodiments, further to the first through eighth embodiments, the metal via is a first metal via, the apparatus further including a second metal via, and a void at the second metal via overlaps an individual one of the voids at the first metal via.

In one or more tenth embodiments, further to the first through ninth embodiments, the metal via is a first metal via, and the plurality of voids is a first plurality of voids, the apparatus further including a second metal via through a second plurality of voids, wherein the first metal via is beneath the IC die, and individual ones of the second plurality of voids have substantially equal radii.

In one or more eleventh embodiments, an apparatus includes a first substrate, an IC package, including an IC die and a second substrate, the IC die coupled to a power supply through the first substrate, a stack of antipads in a stack of layers in the second substrate, and a via extending through one or more of the antipads, wherein the via is within or through a first antipad in a first layer, through a second antipad in a second layer over the first layer, and within or through a third antipad in a third layer over the second layer, and wherein a first diameter of the first antipad is greater than a second diameter of the second antipad, and the second diameter is smaller than a third diameter of the third antipad.

In one or more twelfth embodiments, further to the eleventh embodiments, the via includes a first connection in or under the first layer, a second connection in or over the third layer, a first pad at the first connection, and a second pad at the second connection, wherein the second diameter is equal to or greater than a diameter of the first or second pad.

In one or more thirteenth embodiments, further to the eleventh or twelfth embodiments, the first diameter is substantially equal to the third diameter.

In one or more fourteenth embodiments, further to the eleventh through thirteenth embodiments, the apparatus also includes fourth and fifth antipads in fourth and fifth layers, wherein the fourth and fifth antipads have a fourth diameter, the fourth layer is between the first and the second layers, the fifth layer is between the second and the third layers, the first and third diameters are greater than the fourth diameter, and the fourth diameter is greater than the second diameter.

In one or more fifteenth embodiments, a method includes forming a first conductor having a first antipad in a first layer of a substrate, the first antipad having a first diameter on an axis, forming a second conductor having a second antipad in a second layer, the second antipad having a second diameter on the axis, the first diameter greater than the second diameter, forming a third conductor having a third antipad in a third layer, the third antipad having a third diameter on the axis, wherein the second layer is between the first and third layers, and the third diameter is substantially equal to the first diameter, and forming a via on the axis and in at least the first, second, and third layers.

In one or more sixteenth embodiments, further to the fifteenth embodiments, the method also includes coupling an IC die to the substrate.

In one or more seventeenth embodiments, further to the fifteenth or sixteenth embodiments, coupling the IC die includes coupling the IC die over the via.

In one or more eighteenth embodiments, further to the fifteenth through seventeenth embodiments, the method also includes forming first and second connections to the via, wherein the first connection is in or under the first layer, and the second connection is in or over the third layer.

In one or more nineteenth embodiments, further to the fifteenth through eighteenth embodiments, the method also includes forming a fourth conductor having a fourth antipad in a fourth layer, the fourth antipad having a fourth diameter on the axis, wherein the fourth layer is between the first and third layers, the second layer is at a midpoint of the via or between the fourth layer and the midpoint of the via, the first diameter is greater than the fourth diameter, and the fourth diameter is greater than the second diameter.

In one or more twentieth embodiments, further to the fifteenth through nineteenth embodiments, the method also includes forming a fifth conductor having a fifth antipad in a fifth layer, the fifth antipad having a fifth diameter on the axis, wherein the fifth layer is between the first and third layers, the fifth diameter is substantially equal to the fourth diameter, and the second layer is between the fourth layer and the fifth layer.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a package substrate, comprising a plurality of metal layers and a plurality of voids; and
an integrated circuit (IC) die on the package substrate, wherein the package substrate comprises:
a first metal layer having a first void, the first void having a first radius;
a second metal layer having a second void, the second metal layer over the first metal layer, the second void having a second radius smaller than the first radius;
a third metal layer having a third void, the third metal layer over the second metal layer, the third void having a third radius larger than the second radius; and
a metal via within, and extending through at least one of, the first, second, and third voids.

2. The apparatus of claim 1, wherein a first connection to the metal via is in or under the first metal layer, and a second connection to the metal via is in or over the third metal layer.

3. The apparatus of claim 2, wherein the metal via comprises a first pad at the first connection or a second pad at the second connection.

4. The apparatus of claim 1, wherein the first radius is substantially equal to the third radius.

5. The apparatus of claim 1, wherein a fourth void at the metal via in a fourth metal layer has a fourth radius, the fourth metal layer is between the first and third metal layers, the first and third radii are greater than the fourth radius, and the fourth radius is greater than the second radius.

6. The apparatus of claim 5, wherein a fifth void at the metal via in a fifth metal layer has a fifth radius, the fifth metal layer is between the first and third metal layers, the second metal layer is between the fourth and fifth metal layers, the first and third radii are greater than the fifth radius, and the fifth radius is greater than the second radius.

7. The apparatus of claim 1, wherein:
a void profile around the metal via has a first slope adjacent an end of the metal via;
the void profile has a second slope adjacent a midpoint of the metal via; and
the second slope is greater than the first slope.

8. The apparatus of claim 1, wherein:
the plurality of metal layers comprises at least one pair of the metal layers above or below a midpoint of the metal via;
each such pair comprises a distal metal layer further from the midpoint and an intervening metal layer nearer to the midpoint; and
the distal metal layer comprises a distal void having a radius greater than a radius of an intervening void in the intervening metal layer.

9. The apparatus of claim 1, wherein the metal via is a first metal via, the apparatus further comprising a second metal via, and a void at the second metal via overlaps an individual one of the voids at the first metal via.

10. The apparatus of claim 1, wherein the metal via is a first metal via, and the plurality of voids is a first plurality of voids, the apparatus further comprising a second metal via through a second plurality of voids, wherein the first metal via is beneath the IC die, and individual ones of the second plurality of voids have substantially equal radii.

11. An apparatus, comprising:
a first substrate;
an integrated circuit (IC) package, comprising an IC die and a second substrate, the IC die coupled to a power supply through the first substrate;
a stack of antipads in a stack of layers in the second substrate; and
a via extending through one or more of the antipads, wherein the via is within or through a first antipad in a first layer, through a second antipad in a second layer over the first layer, and within or through a third antipad in a third layer over the second layer, and wherein a first diameter of the first antipad is greater than a second diameter of the second antipad, and the second diameter is smaller than a third diameter of the third antipad.

12. The apparatus of claim 11, wherein the via comprises a first connection in or under the first layer, a second connection in or over the third layer, a first pad at the first connection, and a second pad at the second connection, wherein the second diameter is equal to or greater than a diameter of the first or second pad.

13. The apparatus of claim 12, wherein the first diameter is substantially equal to the third diameter.

14. The apparatus of claim 13, further comprising fourth and fifth antipads in fourth and fifth layers, wherein the fourth and fifth antipads have a fourth diameter, the fourth layer is between the first and the second layers, the fifth layer is between the second and the third layers, the first and third diameters are greater than the fourth diameter, and the fourth diameter is greater than the second diameter.

15. A method, comprising:
forming a first conductor having a first antipad in a first layer of a substrate, the first antipad having a first diameter on an axis;
forming a second conductor having a second antipad in a second layer, the second antipad having a second diameter on the axis, the first diameter greater than the second diameter;
forming a third conductor having a third antipad in a third layer, the third antipad having a third diameter on the axis, wherein the second layer is between the first and third layers, and the third diameter is substantially equal to the first diameter; and
forming a via on the axis and in at least the first, second, and third layers.

16. The method of claim 15, further comprising coupling an integrated circuit (IC) die to the substrate.

17. The method of claim 16, wherein coupling the IC die comprises coupling the IC die over the via.

18. The method of claim 15, further comprising forming first and second connections to the via, wherein the first connection is in or under the first layer, and the second connection is in or over the third layer.

19. The method of claim 15, further comprising forming a fourth conductor having a fourth antipad in a fourth layer, the fourth antipad having a fourth diameter on the axis, wherein the fourth layer is between the first and third layers, the second layer is at a midpoint of the via or between the fourth layer and the midpoint of the via, the first diameter is greater than the fourth diameter, and the fourth diameter is greater than the second diameter.

20. The method of claim 19, further comprising forming a fifth conductor having a fifth antipad in a fifth layer, the fifth antipad having a fifth diameter on the axis, wherein the fifth layer is between the first and third layers, the fifth diameter is substantially equal to the fourth diameter, and the second layer is between the fourth layer and the fifth layer.
